(19) United States
(12) Patent Application Publication
(10) Pub. No.: US 2016/0131683 A1
(43) Pub. Date: May 12, 2016

(54) MAGNETIC SENSOR AND ELECTRICAL CURRENT SENSOR USING THE SAME

(71) Applicant: Panasonic Intellectual Property Management Co., Ltd., Osaka (JP)

(72) Inventors: KAZUHIRO ONAKA, Hyogo (JP); TAKASHI UMEDA, Osaka (JP); SHIGEHIRO YOSHIUCHI, Kyoto (JP); RYO OSABE, Osaka (JP)

(21) Appl. No.: 14/997,538

(22) Filed: Jan. 17, 2016

Related U.S. Application Data
(63) Continuation of application No. PCT/JP2014/003152, filed on Jun. 13, 2014.

(30) Foreign Application Priority Data
Aug. 6, 2013 (JP) 2013-163013

(51) Int. Cl. G01R 15/20; G01R 33/09; G01R 19/00

(52) U.S. Cl. CPC G01R 15/205; G01R 19/0092; G01R 33/09

(57) ABSTRACT

A magnetic sensor has a first tube-shaped bias magnet and a first magnetic sensor element. The first tube-shaped bias magnet has a bottom face, a top face facing the bottom face, and an outer side surface and an inner side surface both located between the bottom face and the top face, and includes an N pole formed by magnetizing one of the bottom face and the top face and an S pole formed by magnetizing a remaining one of the bottom face and the top face. The first magnetic sensor element is located in an inner space surrounded by a plane including the bottom face, a plane including the top face, and the inner side surface. The magnetic sensor can detect intensity of an external magnetic field with high accuracy.

### BACKGROUND

1. Technical Field

The present disclosure relates to a magnetic sensor for detecting a magnetic field and an electric current sensor for measuring current flowing through a conductor using the magnetic sensor.

2. Background Art

A magnetic sensor is known as a detection sensor for detecting a magnetic field. There is known a magnetic sensor that uses a Hall element, a magnetic resistance element, or the like. Further, when the magnetic sensor is used, a method of employing a bias magnet is known. Furthermore, there is known an electric current sensor that uses the magnetic sensor to detect an induction field induced by a current. A Hall element, a magnetic resistance element, or the like is known as the magnetic sensor for the electric current sensor.

As such a bias magnet, there is known a magnetic sensor that uses a tube-shaped magnet (Unexamined Japanese Patent Publication No. 2007-303891).

Further, there is known a technique that disposes a magnetic sensor in a bias magnet (Unexamined Japanese Patent Publication No. 2000-298134).

Additionally, literatures disclosing a relationship between a bias magnet and a magnetic sensor are listed in Unexamined Japanese Patent Publications No. 2010-91346, No. 2008-180603, No. 2006-194837, No. 2006-112801, No. 2005-331295, No. 2001-226091, No. H10-300763, No. 1108-5647, No. H06-76706 and No. H01-175141.

### SUMMARY

The present disclosure provides a high precision magnetic sensor suitable for measuring intensity of an external magnetic field.

A magnetic sensor in accordance with the disclosure includes: a first tube-shaped bias magnet that has a bottom face, a top face facing bottom face, and an outer side surface and an inner side surface both located between the bottom face and the top face, and includes an N-pole formed by magnetizing one of the bottom face and the top face and an S-pole formed by magnetizing a remaining one of the bottom face and the top face; and a first magnetic sensor element located in an inner space surrounded by a plane including the bottom face, a plane including the top face, and the inner side surface.

With the above configuration, for example, the tube-shaped bias magnet has a uniform magnetic field in the inner space. This enables the magnetic sensor to detect an external magnetic field with high accuracy, even in a case where positioning accuracy of the magnetic sensor element is low in the inner space.

Further, an electrical current sensor in accordance with the disclosure includes: a first tube-shaped bias magnet that has a first bottom face, a first top face facing first bottom face, and a first outer side surface and a first inner side surface both located between the first bottom face and the first top face, and includes an N-pole formed by magnetizing one of the first bottom face and the first top face and an S-pole formed by magnetizing a remaining one of the first bottom face and the first top face; a first magnetic sensor element located in an inner space surrounded by a plane including first bottom face, a plane including the first top face, and the first inner side surface; a second tube-shaped bias magnet that has a second bottom face, a second top face facing the second bottom face, and a second outer side surface and a second inner side surface both located between the second bottom face and the second top face, and includes an N-pole formed by magnetizing one of the second bottom face and the second top face and an S-pole formed by magnetizing a remaining one of the second bottom face and the second top face; a second magnetic sensor element located in an inner space surrounded by a plane including the second bottom face, a plane including the second top face, and the second inner side surface; and a current pass disposed between the first tube-shaped bias magnet and the second tube-shaped bias magnet.

With the above configuration, for example, the effect of a disturbance magnetic field can be eliminated. Further, the tube-shaped bias magnets are used and the magnetic sensors are disposed in the inner spaces thereof, respectively. This enables the electrical current sensor to measure current with high accuracy, even in a case where positioning accuracy of the magnetic sensor elements is low.

The magnetic sensor in the disclosure makes it possible to detect an external magnetic field with high accuracy, even in a case where positioning accuracy of the magnetic sensor element is low.

### BRIEF DESCRIPTION OF DRAWINGS

FIG. 1 is a perspective view of a magnetic sensor in accordance with a first embodiment.

FIG. 2 is a side view of the magnetic sensor illustrated in FIG. 1.

FIG. 3 is a front cross-sectional view of the magnetic sensor illustrated in FIG. 1.

FIG. 4 is a front view of a first magnetic sensor element of the magnetic sensor illustrated in FIG. 1.

FIG. 5 is a perspective view of a magnetic sensor in accordance with a second embodiment.

FIG. 6 is a side view of the magnetic sensor illustrated in FIG. 5.

FIG. 7 is a front view of a second magnetic sensor element in the magnetic sensor illustrated in FIG. 5.

### DETAILED DESCRIPTION OF PREFERRED EMBODIMENTS

Prior to the describing exemplary embodiments of the present disclosure, problems in the conventional magnetic sensors will be described briefly.

In recent years, a high precision magnetic sensor with small errors has been required. To achieve high precision properties, there is a method for reducing variations in factors that affect magnetic sensor properties. To do this, it is important to improve positioning accuracy of elements constituting a magnetic sensor. The improvement of positioning accuracy, however, has some limitations.

The magnetic sensor described in Unexamined Japanese Patent Publication No. 2007-303891 utilizes such a phenomenon that, when a magnetic sensor is disposed to protrude from an end of a tube-shaped bias magnet, a magnetic field at the end of the tube-shaped bias magnet is affected by a magnetic material located near the tube-shaped bias magnet, so that the magnetic field is inverted.

In the magnetic sensor described in Unexamined Japanese Patent Publication No. 2000-298134, a surrounding area of a mold IC including a magnetic resistance element is magnetized and molded with a magnetic material. However, the sensors described in these publications are difficult to detect intensity of an external magnetic field with high accuracy.

### First Exemplary Embodiment

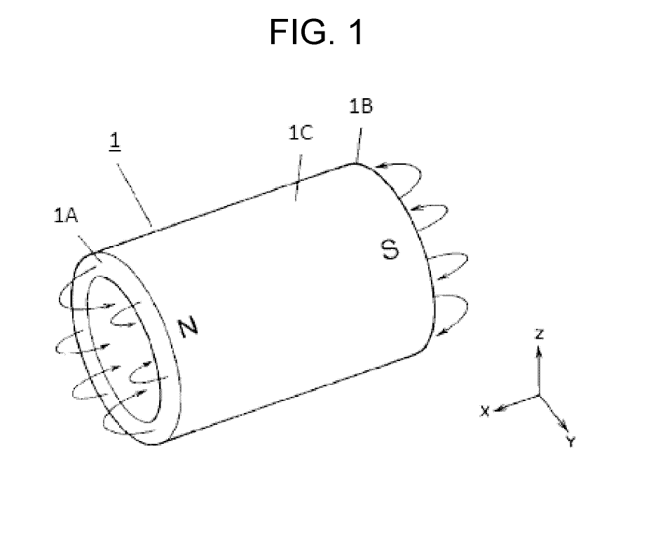

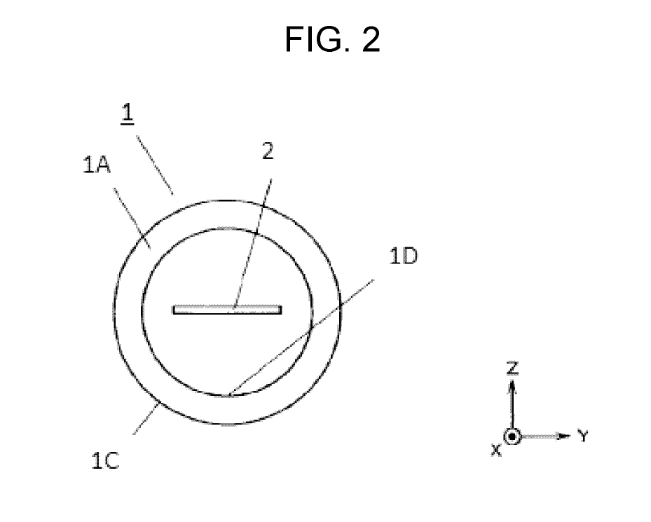

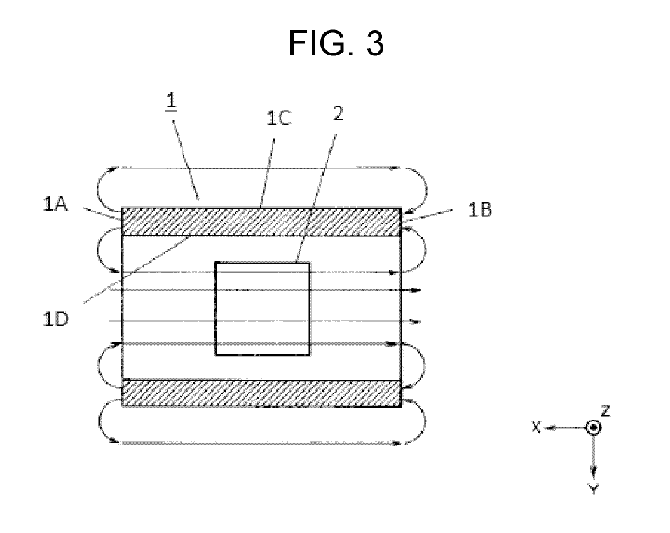

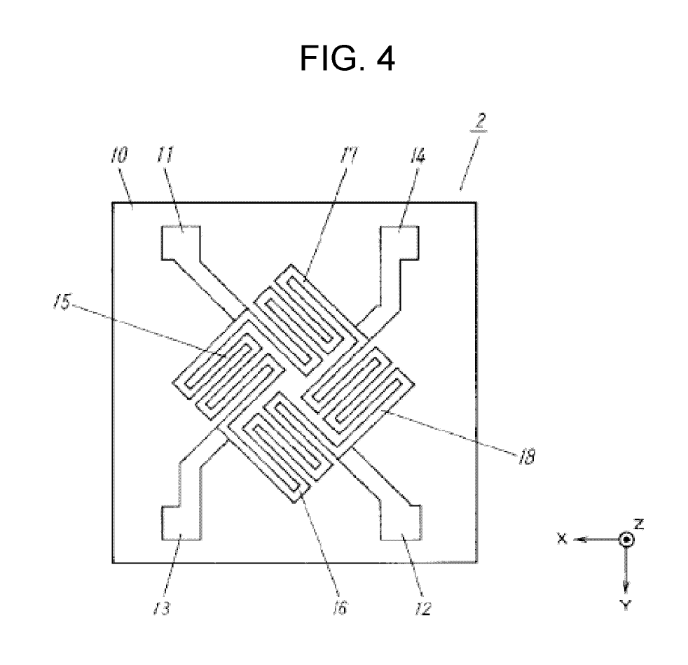

Hereinafter, a magnetic sensor in a first embodiment will be described with reference to the drawings. FIG. 1 is a perspective view of the magnetic sensor in the first embodiment, FIG. 2 is a side view of the magnetic sensor, FIG. 3 is a front cross-sectional view of the magnetic sensor, and FIG. 4 is a front view of a first magnetic sensor element in the magnetic sensor.

Herein, in FIGS. 1 to 4, X axis indicates an axis direction of first tube-shaped bias magnet 1, Y axis indicates a direction parallel to a face of first substrate 10 of first magnetic sensor element 2 among radial directions of first tube-shaped bias magnet 1, and Z axis indicates a direction perpendicular to the face of first substrate 10 of first magnetic sensor element 2 among the radial directions of first tube-shaped bias magnet 1. X axis, Y axis, and Z axis are perpendicular to one another.

As shown in FIG. 1, first tube-shaped bias magnet 1 with a tube shape has bottom face 1A, top face 1B facing bottom face 1A, outer side surface 1C, and inner side surface 1D. Outer side surface 1C is located between bottom face 1A and top face 1B and serves as an external side of the tube. Inner side surface 1D is located between bottom face 1A and top face 1B and serves as an internal side of the tube. Herein, the shape of the tube is preferably cylindrical as shown in FIG. 1. Bottom face 1A and top face 1B are preferable to have an annular shape, but not limited to this. For instance, the outline of the tube may be a quadrangular prism. Note that, a space surrounded by a plane including bottom face 1A, a plane including top face 1B, and inner side surface 1D, i.e., a space inside the tube is called an inner space. First tube-shaped bias magnet 1 has an N-pole at bottom face 1A which is an end in a positive direction of X axis and an S-pole at top face 1B which is an end in a negative direction of X axis. Magnetic fluxes are emitted from the N-pole. Some reach the S-pole through the outside and some reach the S-pole through the inner space of first tube-shaped bias magnet 1.

The outline of first tube-shaped bias magnet 1 is a column. Within the column, first tube-shaped bias magnet 1 has a columnar inner space with a volume smaller than that of the column. As shown in FIG. 2, the cross section of first tube-shaped bias magnet 1 taken along a plane parallel to a Y-Z plane is annular, that is, the outer side and the inner side are circular. As shown in FIG. 3, the cross section of first tube-shaped bias magnet 1 taken along an X-Y plane shows linear lines in an X axis direction. Thus, the magnetic fluxes passing through the inner space of first tube-shaped bias magnet 1 are substantially parallel to an extending direction of the tube. The magnetic fluxes passing through the inner space are uniformly provided in the inner space. In other word, the magnetic field is uniform in the inner space. Herein, the inner side surface of first tube-shaped bias magnet 1 is preferably smooth. If the inner surface of first tube-shaped bias magnet 1 is uneven, the magnetic fluxes passing through the inside of first tube-shaped bias magnet 1 are difficult to be substantially parallel.

First magnetic sensor element 2 is disposed in the inner space. Further, first magnetic sensor element 2 is preferably positioned in a center of first tube-shaped bias magnet 1 in a plan view. The magnetic field in a center of the inner space of first tube-shaped bias magnet 1 has higher uniformity than the magnetic field in an end portion of the inner space. Herein, the center of first tube-shaped bias magnet 1 in a plan view and the center of the inner space indicate a center in an axis direction in which first tube-shaped bias magnet 1 extends. Therefore, disposing first magnetic sensor element 2 in the center of first tube-shaped bias magnet 1 in a plan view allows an external magnetic field to be detected more accurately.

As shown in FIG. 4, for example, first magnetic sensor element 2 is so structured that a magnetic resistive element is formed on a surface of first substrate 10 made of alumina. Specifically, on the surface of first substrate 10, first voltage applying terminal 11, first ground terminal 12, first output terminal 13, and second output terminal 14 are formed. Further, first magnetic resistor pattern 15 is formed between first voltage applying terminal 11 and first output terminal 13. Second magnetic resistor pattern 16 is formed between first output terminal 13 and first ground terminal 12. Third magnetic resistor pattern 17 is formed between first voltage applying terminal 11 and second output terminal 14. Fourth magnetic resistor pattern 18 is formed between second output terminal 14 and first ground terminal 12. First magnetic sensor element 2 has a full bridge circuit constituted by first magnetic resistor pattern 15, second magnetic resistor pattern 16, third magnetic resistor pattern 17, and fourth magnetic resistor pattern 18.

Each of these magnetic resistor patterns is constituted by a magnetic resistive element whose resistance is changed when a magnetic field is applied thereto. For instance, as a magnetic resistive element, Magneto Resistance (MR) or Giant Magneto Resistance (GMR) may be used. This embodiment employs MR. Each of these magnetic resistor patterns is formed in a meandering shape. In first magnetic resistor pattern 15 and fourth magnetic resistor pattern 18, a longitudinal direction of each magnetic resistor pattern is tilted 45 degrees from X axis. The tilt is directed from a positive direction of X axis and a positive direction of Y axis to a negative direction of X axis and a negative direction of Y axis. In second magnetic resistor pattern 16 and third magnetic resistor pattern 17, a longitudinal direction of each magnetic resistor pattern is tilted 45 degrees from X axis. The tilt is directed from the positive direction of X axis and the negative direction of Y axis to the negative direction of X axis and the positive direction of Y axis. That is, the longitudinal direction of first magnetic resistor pattern 15 is tilted 90 degrees with respect to the longitudinal direction of second magnetic resistor pattern 16. The longitudinal direction of third magnetic resistor pattern 17 is tilted 90 degrees with respect to the longitudinal direction of fourth magnetic resistor pattern 18. MR is sensitive to a magnetic field in a direction in an in-plane direction of the magnetic resistor pattern, i.e., in a direction perpendicular to a direction in which current flows in an X-Y plane of FIG. 4, and its resistance is changed. The direction perpendicular to the longitudinal direction of each pattern is a main direction sensitive to a magnetic field because each magnetic resistor pattern has a meandering shape. Accordingly, first magnetic resistor pattern 15 and fourth magnetic resistor pattern 18 have the same magnetic field sensitive direction. Second magnetic resistor pattern 16 and third magnetic resistor pattern 17 have the same magnetic field sensitive direction. The magnetic field sensitive direction of each of fourth magnetic resistor pattern 18 and first magnetic resistor pattern 15 is perpendicular to the magnetic field sensitive direction of each of second magnetic resistor pattern 16 and third magnetic resistor pattern 17.

First magnetic resistor pattern 15, second magnetic resistor pattern 16, third magnetic resistor pattern 17, and fourth magnetic resistor pattern 18 have the same resistance when no magnetic field is applied thereto. When a magnetic field is applied, the above magnetic resistor patterns also provides the same change in resistance. Accordingly, these four magnetic resistor patterns have the same resistance when the same magnetic field is applied in the magnetic field sensitive direction.

The principle of operation of the magnetic sensor with the above configuration will be described.

A predetermined voltage is applied between first voltage applying terminal 11 and first ground terminal 12. First output terminal 13 outputs intermediate potential V1 between those at first magnetic resistor pattern 15 and second magnetic resistor pattern 16. Likewise, second output terminal 14 outputs intermediate potential V2 between those at third magnetic resistor pattern 17 and fourth magnetic resistor pattern 18. By measuring the differential output between intermediate potential V1 and intermediate potential V2, an output of first magnetic sensor element 2 is obtained.

When no magnetic field is applied from the outside, only a bias magnetic field from first tube-shaped bias magnet 1 is applied to the respective resistor patterns. In this situation, each resistor pattern has the same resistance. Electrical potentials of first output terminal 13 and second output terminal 14 are the same. Therefore, the differential output is 0 V.

When a magnetic field is applied from the outside, a combined magnetic field of the applied magnetic field and a bias magnetic field caused by first tube-shaped bias magnet 1 is applied to first magnetic sensor element 2. First magnetic resistor pattern 15 and fourth magnetic resistor pattern 18 have the same change in resistance when a magnetic field is applied. Second magnetic resistor pattern 16 and third magnetic resistor pattern 17 also have the same change in resistance when a magnetic field is applied. An increase and decrease direction of the former resistance is reverse to that of the latter resistance. Thus, an output variation due to the differential output between first output terminal 13 and second output terminal 14 is twice as large as an output variation of intermediate potential V1 or intermediate potential V2.

At this time, the change in resistance with respect to each magnetic resistor pattern is determined by magnitude and a direction of the combined magnetic field of the bias magnetic field and the external magnetic field. Accordingly, even if only the differential output between first output terminal 13 and second output terminal 14 is obtained, the magnitude of the magnetic field is not determined unambiguously. However, if the direction of the magnetic field is determined, for example, to be an X axis direction in advance, a differential output corresponding to the magnitude of the magnetic field can be obtained. This makes it possible to use the magnetic sensor.

The magnetic sensor in accordance with the embodiment has first magnetic sensor element 2 disposed inside first tube-shaped bias magnet 1. Thus, high positioning accuracy of first magnetic sensor element 2 is not necessary because the magnetic field inside first tube-shaped bias magnet 1 is uniform. In other word, the uniformity of the magnetic field permits an arbitrary positioning in the X axis direction, the Y axis direction, and the Z axis direction. But, the magnetic field at the end portion of first tube-shaped bias magnet 1 is easy to be affected by an external magnetic field and not always uniform. Therefore, in the X axis direction, it is preferable to select a position well away from the end portion of first tube-shaped bias magnet 1, where the magnetic field is uniform.

In the magnetic sensor in accordance with the embodiment, the bias magnetic field is applied to first magnetic sensor element 2 uniformly. Accordingly, the uniform magnetic field is applied to each of first magnetic resistor pattern 15, second magnetic resistor pattern 16, third magnetic resistor pattern 17, and fourth magnetic resistor pattern 18. Therefore, the direction and the magnitude of the bias magnetic field with respect to four magnetic resistor patterns are equal.

Accordingly, the direction and the magnitude of the combined magnetic field, which is combined by the external magnetic field applied to each resistor pattern and the bias magnetic field, are constant. This reduces measurement errors due to variability of the bias magnetic field.

### Second Exemplary Embodiment

A magnetic sensor in a second embodiment will be described. The magnetic sensor in the second embodiment employs first magnetic sensor element 2 and second magnetic sensor element 5. The magnetic sensor is allowed to detect current characteristics flowing through a current path, thereby functioning as an electrical current sensor.

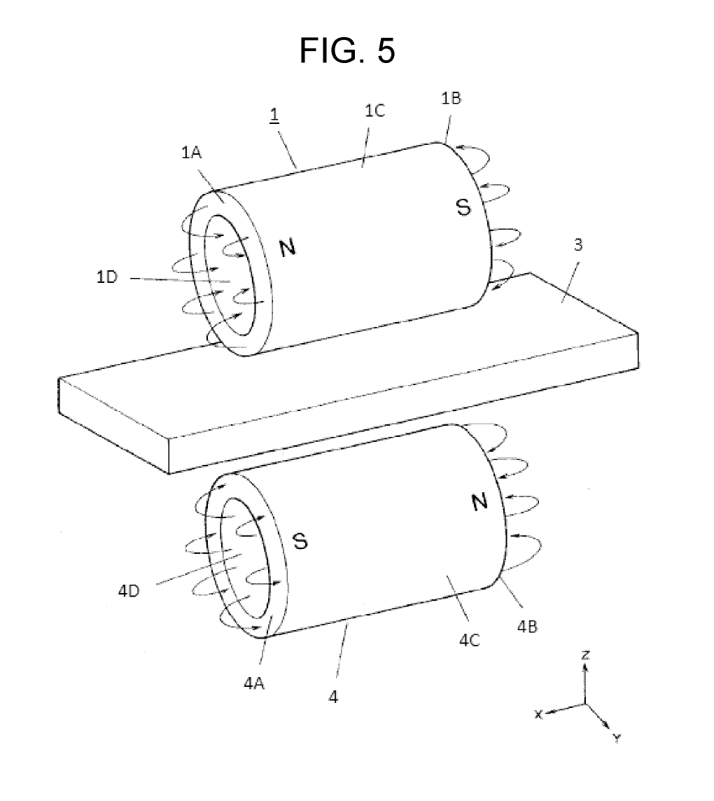

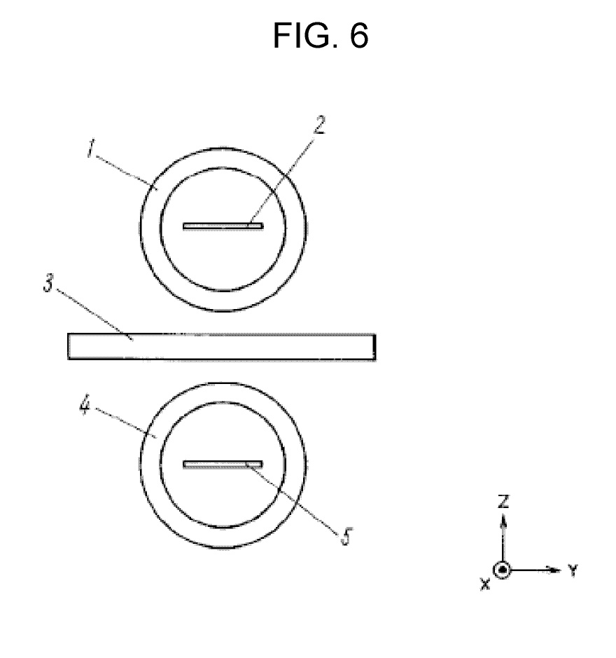

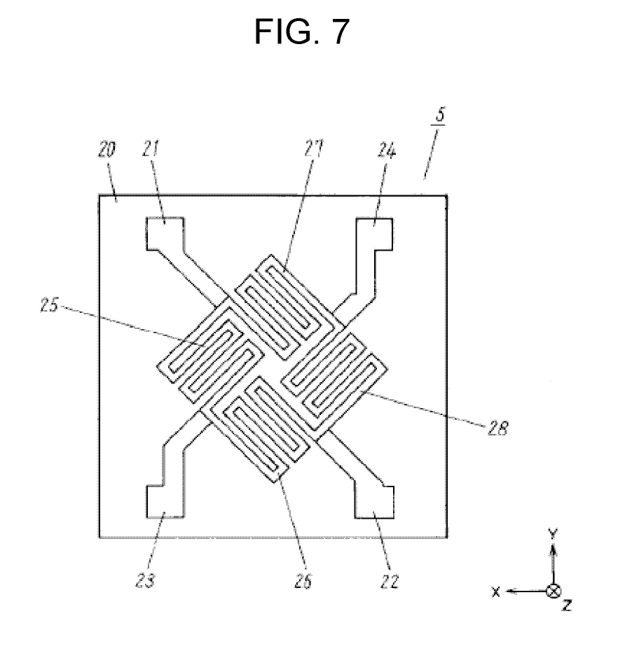

FIG. 5 is a perspective view of the magnetic sensor in accordance with the second embodiment. FIG. 6 is a side view of the magnetic sensor. FIG. 7 is a front view of a second magnetic sensor element in the magnetic sensor. Among reference numerals in the figures, the same reference numerals may be assigned to the same components as the first embodiment.

As shown in FIG. 5, current bar 3 as a current path is disposed in a negative direction of Z axis with respect to first tube-shaped bias magnet 1. Second tube-shaped bias magnet 4 is disposed in a negative direction with respect to Z axis of current bar 3. Second tube-shaped bias magnet 4 has the same tube shape as first tube-shaped bias magnet 1. Second tube-shaped bias magnet 4 has bottom face 4A, top face 4B, and outer side surface 4C and inner side surface 4D both located between bottom face 4A and top face 4B. Herein, the shape of the tube is preferably cylindrical, and each of bottom face 4A and top face 4B is preferable to have an annular shape, but not limited to this. For instance, the outline of the tube may be a quadrangular prism. Note that, also in second tube-shaped bias magnet 4, a space surrounded by a plane including bottom face 4A, a plane including top face 4B, and inner side surface 4D, i.e., a space inside the tube is called an inner space. Herein, an axis direction of second tube-shaped bias magnet 4 is preferably parallel to the axis direction of first tube-shaped bias magnet 1. A magnetic pole direction of second tube-shaped bias magnet 4 is preferably reverse to the magnetic pole direction of first tube-shaped bias magnet 1. Note that, bottom face 4A corresponding to an end portion of second tube-shaped bias magnet 4 in the positive direction of X axis is an S-pole, and top face 4B corresponding to an end portion of second tube-shaped bias magnet 4 in the negative direction of X axis is an N-pole. Magnetic fluxes are emitted from the N-pole. Some reach the S-pole through the outside and some reach the S-pole through the inner space of second tube-shaped bias magnet 4, like first tube-shaped bias magnet 1. Second tube-shaped bias magnet 4 also has a uniform magnetic field in the inner space.

As shown in FIG. 6, second magnetic sensor element 5 is disposed in the inner space of second tube-shaped bias magnet 4. Second substrate 20 of second magnetic sensor element 5 is disposed so as to be parallel to an X-Y plane. Herein, second magnetic sensor element 5 is preferably positioned in a center of second tube-shaped bias magnet 4 in a plan view. The magnetic field in a center of the inner space of second tube-shaped bias magnet 4 has higher uniformity than the magnetic field in an end portion of the inner space. Therefore, when second magnetic sensor element 5 is disposed in the center of second tube-shaped bias magnet 4 in a plan view, an external magnetic field can be detected more accurately.

As shown in FIG. 7, second magnetic sensor element 5 has the same configuration as first magnetic sensor element 2. For instance, a magnetic resistive element is formed on a surface of second substrate 20 made of alumina. Specifically, second magnetic sensor element 5 has the following structure. On the surface of second substrate 20, second voltage applying terminal 21, second ground terminal 22, third output terminal 23, and fourth output terminal 24 are provided.

Further, fifth magnetic resistor pattern 25 is connected to second voltage applying terminal 21 and third output terminal 23 therebetween. Sixth magnetic resistor pattern 26 is connected to third output terminal 23 and second ground terminal 22 therebetween. Seventh magnetic resistor pattern 27 is connected to second voltage applying terminal 21 and fourth output terminal 24 therebetween. Eighth magnetic resistor pattern 28 is connected to fourth output terminal 24 and second ground terminal 22 therebetween. Fifth magnetic resistor pattern 25, sixth magnetic resistor pattern 26, seventh magnetic resistor pattern 27, and eighth magnetic resistor pattern 28 are constituted by a magnetic resistive element whose resistance is changed when a magnetic field is applied. As the magnetic resistive element, for example, MR and GMR are used. In this embodiment, MR is employed. These magnetic resistor patterns are formed in a meandering shape. A longitudinal direction of each of fifth magnetic resistor pattern 25 and eighth magnetic resistor pattern 28 is tilted 45 degrees form X axis. The tilt is directed from a negative direction of X axis and a positive direction of Y axis to a positive direction of X axis and a negative direction of Y axis. A longitudinal direction of each of sixth magnetic resistor pattern 26 and seventh magnetic resistor pattern 27 is tilted 45 degrees form X axis. The tilt is directed from the positive direction of X axis and the positive direction of Y axis to the negative direction of X axis and the negative direction of Y axis.

If current flows through current bar 3 in the X axis direction, an induction field induced by the current is applied to first magnetic sensor element 2, which is located above current bar 3, in the negative direction of Y axis. On the other hand, the induction field is applied to second magnetic sensor element 5 in the positive direction of Y axis. Consequently, the direction in which the induction field is applied to first magnetic sensor element 2 is opposite to that to second magnetic sensor element 5.

Also, in second magnetic sensor element 5, a combined magnetic field of the bias magnetic field caused by second tube-shaped bias magnet 4 and the induction field caused by current bar 3 changes resistance of the respective resistor patterns.

Herein, when the current flowing through current bar 3 increases, the direction of the combined magnetic field approaches a direction parallel to the longitudinal direction of first magnetic resistor pattern 15 and a direction perpendicular to the longitudinal direction of second magnetic resistor pattern 16. Thus, the resistance of first magnetic resistor pattern 15 is increased and the resistance of second magnetic resistor pattern 16 is decreased, relatively. Accordingly, intermediate potential V1 at first output terminal 13 is decreased. Likewise, intermediate potential V2 at second output terminal 14 is increased. Therefore, a value subtracting intermediate potential V2 from intermediate potential V1 i.e. output voltage V5 from first magnetic sensor element 2 is decreased. At this time, the variation in output voltage V5 before and after the current flowing through current bar 3 increases is larger than those in intermediate voltages V1 and V2.

On the other hand, when the current flowing through current bar 3 decreases, intermediate potential V1 is increased and intermediate potential V2 is decreased vice versa. Thus, output voltage V5 is increased. At this time, the variation in output voltage V5 before and after the current flowing through current bar 3 decreases is larger than those in intermediate voltages V1 and V2.

Consequently, output voltage V5, which is a differential output subtracting intermediate potential V2 from intermediate potential V1, can obtain a large output variation with respect to the change in current.

Likewise, in second magnetic sensor element 5, when the current flowing through current bar 3 increases, intermediate potential V3 of third output terminal 23 is increased and intermediate potential V4 of fourth output terminal 24 is decreased. When the current flowing through current bar 3 decreases, intermediate potential V3 is decreased and intermediate potential V4 of fourth output terminal 24 is increased. Accordingly, output voltage V6, which is a differential output subtracting intermediate potential V4 from intermediate potential V3, can obtain a large output variation with respect to the change in current. The change is in the reverse direction to the change in output voltage V5. Therefore, output voltage V7, which is a differential output subtracting intermediate potential V6 from intermediate potential V5, will obtain a larger output variation.

A magnetic field, other than the magnetic field to be measured caused by current, such as geomagnetism may be applied to the magnetic sensor. Such a magnetic field is called a disturbance magnetic field. Since the disturbance magnetic field may amplify measurement errors, the effect of the disturbance magnetic field is preferably eliminated.

With the above configuration, in the magnetic sensor of the embodiment, the induction field from current bar 3 is applied to first magnetic sensor element 2 and second magnetic sensor element 5 in the reverse direction to each other. The bias magnetic field is also applied to first magnetic sensor element 2 and second magnetic sensor element 5 in the reverse direction to each other. However, a disturbance magnetic field is applied in the same direction. By using this, the effect of a disturbance magnetic field on output voltage V7 can be eliminated. Thus, directions in which the induction field induced by the current flowing through the current path such as current bar 3 is applied to first magnetic sensor element 2 and second magnetic sensor element 5 are preferably different by 180 degrees from each other.

As means for generating bias magnetic fields, first tube-shaped bias magnet 1 and second tube-shaped bias magnet 4 are employed. Like the first embodiment, even if the positioning accuracy of first magnetic sensor element 2 and second magnetic sensor element 5 is not so high, high accurate measurement can be achieved.

The magnetic sensor in accordance with the present disclosure is useful for a magnetism measuring sensor. Further, the magnetic sensor can be used as an electrical current sensor of a principle in which the magnetic sensor detects an induction field induced by current.

What is claimed is:

1. A magnetic sensor, comprising:
a first tube-shaped bias magnet having a bottom face, a top face facing the bottom face, an outer side surface and an inner side surface both located between the bottom face and the top face, and including an N pole formed by magnetizing one of the bottom face and the top face and an S pole formed by magnetizing a remaining one of the bottom face and the top face; and
a first magnetic sensor element located in an inner space surrounded by a plane including the bottom face, a plane including the top face, and the inner side surface.

2. The magnetic sensor according to claim 1,
wherein the first magnetic sensor element is located in a center of the first tube-shaped bias magnet in a plan view.

3. The magnetic sensor according to claim 1,
wherein the first magnetic sensor element has a first magnetic resistor pattern, and
a longitudinal direction of the first magnetic resistor pattern is tilted 45 degrees with respect to a longitudinal direction of the first tube-shaped bias magnet.

4. The magnetic sensor according to claim 3,
wherein the first magnetic sensor element further has a second magnetic resistor pattern, and
the longitudinal direction of the first magnetic resistor pattern is tilted 90 degrees with respect to a longitudinal direction of the second magnetic resistor pattern.

5. The magnetic sensor according to claim 4,
wherein the first magnetic sensor element further has third and fourth magnetic resistor patterns,
a longitudinal direction of the fourth magnetic resistor pattern is tilted 45 degrees with respect to the longitudinal direction of the first tube-shaped bias magnet, and
a longitudinal direction of the third magnetic resistor pattern is tilted 90 degrees with respect to the longitudinal direction of the fourth magnetic resistor pattern.

6. The magnetic sensor according to claim 1,
wherein the first tube-shaped bias magnet has a magnetic field in an end portion of the inner space and a magnetic field in a center of the inner space with higher uniformity than the magnetic field in the end portion of the inner space.

7. An electrical current sensor comprising:
a first tube-shaped bias magnet having a first bottom face, a first top face facing the first bottom face, and a first outer side surface and a first inner side surface both located between the first bottom face and the first top face, and including an N pole formed by magnetizing one of the first bottom face and the first top face and an S pole formed by magnetizing a remaining one of the first bottom face and first the top face;
a first magnetic sensor element located in an inner space surrounded by a plane including the first bottom face, a plane including the first top face, and the first inner side surface;
a second tube-shaped bias magnet having a second bottom face, a second top face facing the bottom face, and a second outer side surface and a second inner side surface both located between the second bottom face and the second top face, and including an N pole formed by magnetizing one of the second bottom face and the second top face and an S pole formed by magnetizing a remaining one of the second bottom face and the second top face;
a second magnetic sensor element located in an inner space surrounded by a plane including the second bottom face, a plane including the second top face, and the second inner side surface; and
a current path disposed between the first tube-shaped bias magnet and the second tube-shaped bias magnet.

8. The electrical current sensor according to claim 7,
wherein a center axis of the second tube-shaped bias magnet is parallel to a center axis of the first tube-shaped bias magnet.

9. The electrical current sensor according to claim 7,
wherein a direction of a magnetic field passing through the inner space of the second tube-shaped bias magnet is opposite to a direction of a magnetic field passing through the inner space of the first tube-shaped bias magnet.

10. The electrical current sensor according to claim 7,
wherein directions in which an induction field induced by current flowing through the current path is applied to the first magnetic sensor element and the second magnetic sensor element are different by 180 degrees from each other.
